(19) United States
(12) Patent Application Publication
(10) Pub. No.: US 2007/0182290 A1
(43) Pub. Date: Aug. 9, 2007

(54) Fabrication of Broadband Graded Transducer Using Piezoelectric Partial Composites

(75) Inventors: Hongkai Guo, San Diego, CA (US); Jon Cannata, Los Angeles, CA (US); K. Kirk Shung, Monterey Park, CA (US)

Correspondence Address: McDERMOTT WILL & EMERY LLP, Suite 3400, 2049 Century Park East, Los Angeles, CA, 90067, US

(73) Assignee: University of Southern California

(21) Appl. No.: 11/458,784

(22) Filed: Jul. 20, 2006

Related U.S. Application Data
(60) Provisional application No. 60/701,761, filed on Jul. 22, 2005.

(51) Int. Cl. H01L 41/08

(52) U.S. Cl. 310/367

(57) ABSTRACT

Broadband ultrasound imaging is capable of achieving superior resolution in clinical applications. An effective and easy way of manufacturing broadband transducers is desired for these applications. In this work, a partial composite in which the piezoelectric plate is mechanically graded with a number of rectangular grooves is introduced. Finite Element Analysis (FEA) demonstrated that the partial composite could easily obtain multiple resonant modes, which resulted in a broadband time-domain response. Experimental tests were carried out to validate the theoretical results. Based upon the FEA designs, several single-element transducers were fabricated using either a non-diced ceramic or a diced partial composite. A superior bandwidth of 92% was achieved by the partial composite transducer when compared to a bandwidth of 56% produced by the non-diced ceramic transducer.

### CROSS-REFERENCE TO RELATED APPLICATION

This application is based upon and claims priority to U.S. Provisional Patent Application Ser. No. 60/701,761, entitled “Fabrication of Broadband Graded Transducer Using Piezoelectric Partial Composites,” filed Jul. 22, 2005, attorney docket number 28080-181, the entire content of which (including its attachments) is incorporated herein by reference.

### STATEMENT REGARDING FEDERALLY SPONSORED RESEARCH

This invention was made with government support under the National Institutes of Health Grant No. P41-EB2192. The government may have certain rights in the invention.

### INTRODUCTION

Ultrasonic transducers have been widely used in various fields including nondestructive evaluation, medical diagnosis and therapy. The need for improved image resolution has prompted intensive studies in developing broadband transducers. Broadband transducers not only satisfy the requirement of the improved spatial resolution, but also offer the advantage of allowing for harmonic imaging.

Since the 1950s optimizing matching layers has been explored as a means of designing broadband transducers (see R. E. Collin, “Theory and Design of Wide-Band Multisection Quarter-Wave Transformers,” Proc. IRE, pp 179-186 February 1955; and C. S. Desilets, J. D. Fraser, and G. S. Kino, “The Design of Efficient Broad-Band Piezoelectric Transducers,” IEEE Trans. Sonics and Ultrason., Vol. SU-25, no. 3, pp. 115-125, 1978, both of which are incorporated herein by reference). Sonar or underwater transducers because of their large size are more amenable for performance enhancement via structural modification (see S. C. Butler, “Triply Resonant Broadband Transducers,” Oceans MTS/IEEE, Vol. 4, PP. 1334-1341, 2002; and R. F. W. Coates, “The Design of Transducers and Arrays For Underwater Data Transmission,” IEEE J. of Oceanic Eng., vol. 16, n0.1, pp. 123-135, 1991, both of which are incorporated herein by reference). Butler (cited above) reported that adding an inactive compliant material in the middle of tonpilz transducer could produce triple resonances, causing a broad-bandwidth response. Coates (cited above) showed a compound-head transducer design intended to offer broadband behavior. These works proved that compound-structures of active multiple piezoelectric layers or inactive materials may be useful to produce multiple resonances and broadband performance. Other ways to produce a broad-bandwidth response are through creating piezoelectric-polymer composites (see W. Hackenberger, X. Jiang, P. Rehrig, X. Geng, A. Winder, F. Forsberg, “Broad Band Single Crystal Transducer For Contrast Agent Harmonic Imaging,” 2003, IEEE Ultrasonic Symposium, pp. 778-781, 2003, incorporated herein by reference), or by altering the internal composition of various single crystal materials (see Q. F. Zhou, J. Cannata, C. Z. Huang, H. K. Guo, V. Marmarelis, and K. K. Shung, “Fabrication and Modeling of Inversion Layer Ultrasonic Transducers Using LiNbO3 Single Crystal,” 2003 IEEE International Ultrasonics Symposium, pp. 1035-1037, 2003; and K. Nakamura, K. Fukazawa, K. Yamada, S. Saito, “Broadband Ultrasonic Transducers Using A LiNbO3 Plate With A Ferroelectric Inversion Layer Ultrasonics,” IEEE Trans. Ultrason., Ferroelect., Freq. Contr., vol. 50, no. 11, pp. 1558-1562, 2003, both of which are incorporated herein by reference). In graded transducers the structural characteristics of the piezoelectric material is physically changed, which may be one of the more effective and more easily manufactured methods to achieve broad bandwidth (see K. Yamada, J. I. Sakamura, and K. Nakamura, “Broadband Transducer Using Effectively Graded Piezoelectric Plates for Generation of Short-Pulse Ultrasound,” Jpn. J. Appl. Phys., Vol. 38, Pt. 1, pp. 3204-3207, 1999; and K. Yamada, J. I. Sakamura, and K. Nakamura, “Equivalent Network Representation for Thinkness Vibration Modes in Piezoelectric Plates with a Linearly Graded Parameter,” IEEE Trans. Ultrason., Ferroelect., Freq. Contr., Vol. 48, no. 2, pp. 613-616, 2001, both of which are incorporated herein by reference). Physically graded piezoelectric ceramic transducers are constructed by mechanically dicing a number of fine triangular V-grooves (kerfs) into one surface of a piezoelectric plate. The graded transducer is believed to have a broadband performance because the graded piezoelectric material has an effectively graded piezoelectric parameter and/or applied electric field which was supposed to result in the broadband performance.

### BRIEF DESCRIPTION OF DRAWINGS

FIG. 1 is a scanning electron micrograph of partial 2-2 composite with rectangular kerfs.

FIG. 2 shows FEA modeling results of resonant impedances of 2-2 partial composite with air kerf filler (a), 2-2 composite with silver/epoxy kerf filler (b), partial composite transducer (c), and pulse-echo of partial composite transducer (d).

FIG. 3 shows experimental results of graded transducer, (a) single partial composite without kerf filler, (b) partial composite with the silver/epoxy filler, (c) graded transducer, (d) pulse-echo measurements, (e) pulse-echo results of uniform ceramics transducer.

### PARTIAL COMPOSITES AND TRANSDUCER FABRICATION

Partial Composites

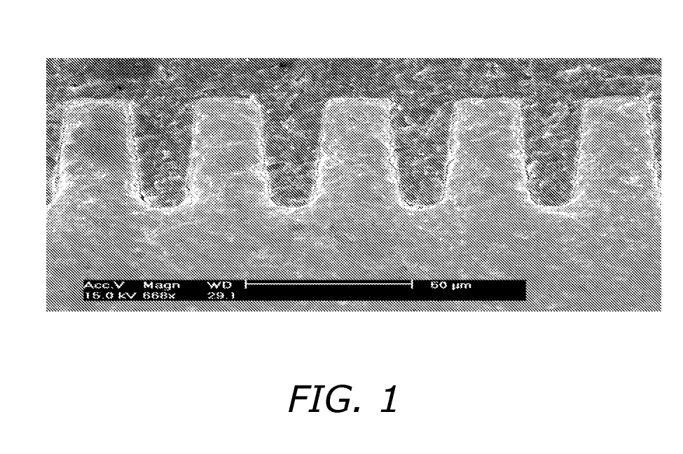

Since the V-groove kerfs of the graded piezoelectric plate have to be diced using particular blades, and the slope of the triangles might affect the acoustic field distribution. It then appeared that rectangular kerfs might be an easier way for providing graded piezoelectric plates. Rectangular kerfs were diced on a surface of ceramics with depth that is less than half of the ceramics' total thickness, one direction dicing would result in a half thickness 2-2 composite and two directions dicing would result in a half 1-3 composite (Remove). After the polymer filler was applied to the kerfs, the resultant active transducer material consisted of one half of 2-2 or 1-3 composite and one half of monolithic ceramic, effectively forming a partial 2-2 or 1-3 composite. In this study, circular plates of PbTiO₃ (PT) ceramics (EDO, t=150 μm, R=3 mm) were used to make graded transducer, kerfs were diced on one side of the plate by a mechanical dicing saw with a 20 μm width blade. The pitch was 40 μm. An SEM image of the composite cross-section is shown in FIG. 1.

Transducer Fabrication

The transducers were fabricated using 2-2 partial composite shown in FIG. 1. A λ/4 silver epoxy matching layer made from a mixture of three parts 2-3 μm silver particles (Adrich Chem. Co., Milwaukee, Wis.) and 1.25 parts Insulcast 501 epoxy (American Safety Technologies, Roseland, N.J.) was cast onto the negative electrode side (diced side) with the aid of an adhesion promoter (Chemlok AP-131, Lord Corp., Erie, Pa.). This matching layer was centrifuged at 2000 g for 10 minutes to increase the acoustical impedance and to ensure conductivity over the entire active aperture. The material properties of the passive materials and PT ceramics can be found in published papers [10,11]. After curing, the matching layer was lapped down to approximately λ/4 thickness using a coarse-to-fine grit scheme, with a final lapping particle diameter of 12 μm. A lossy conductive epoxy (E-SOLDER 3022, Von Roll Isola Inc., New Haven, Conn.) then was cast on the wafer as the backing material. A lathe was used to shape the matching, piezoelectric, and backing layers into the desired acoustic stack diameter. This fabrication step also served to electrically isolate the conductive matching and backing layers. The positive lead wire was secured to the backing layer with an additional amount of conductive epoxy. A layer of chrome/gold then was sputtered across the transducer face. Final transducers were housed in modified SMA connectors. (What about the second matching layer? You didn't talk about that at all!)

In order to compare the performance of the graded transducer and regular ceramic transducer, a regular bulk PbTiO₃ ceramic transducer was built. The un-graded flat PbTiO₃ transducer using a ceramic thickness of 140 μm.

Finite Element Analysis

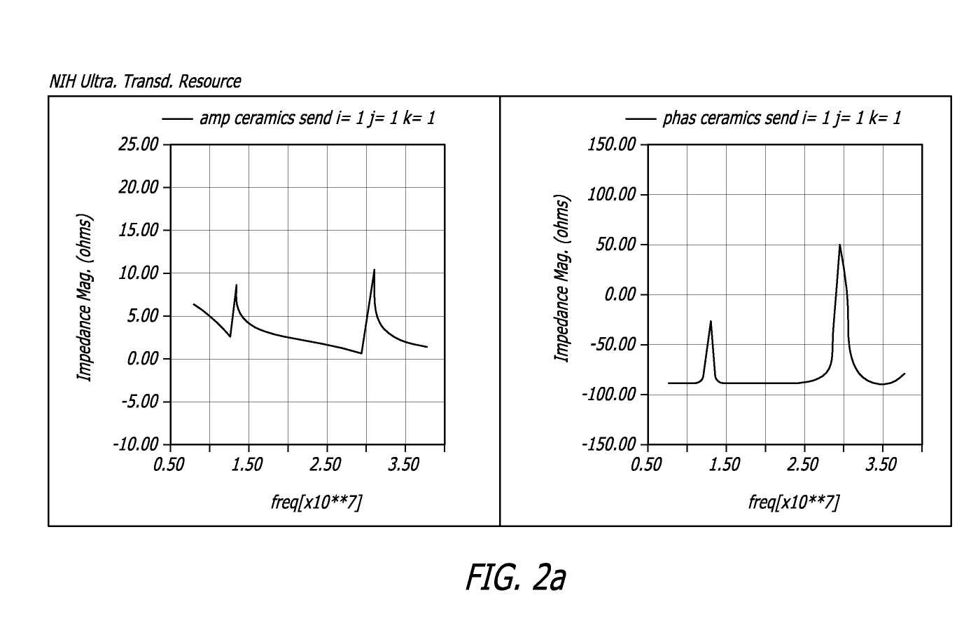

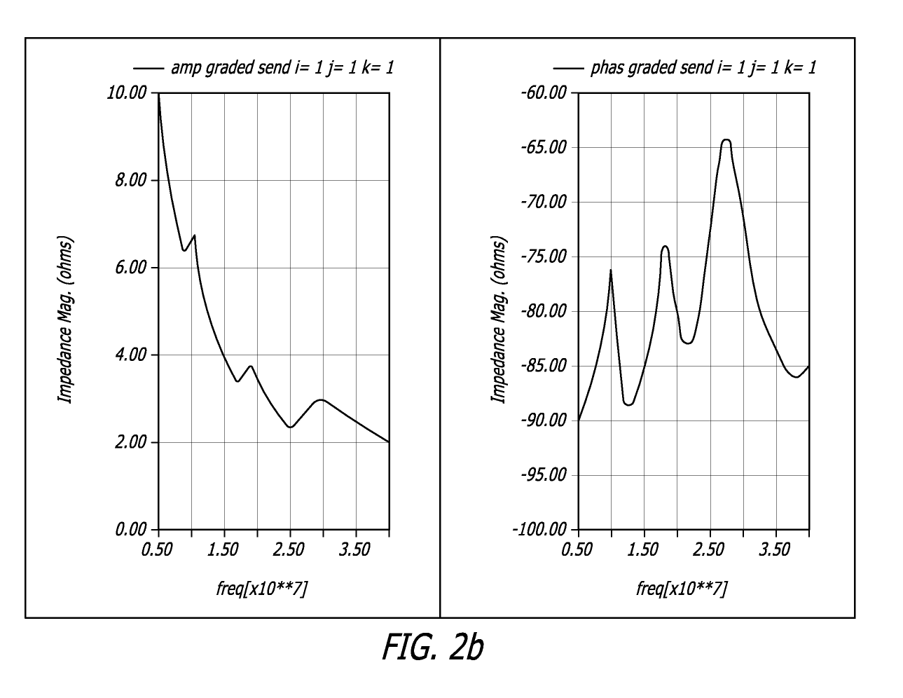

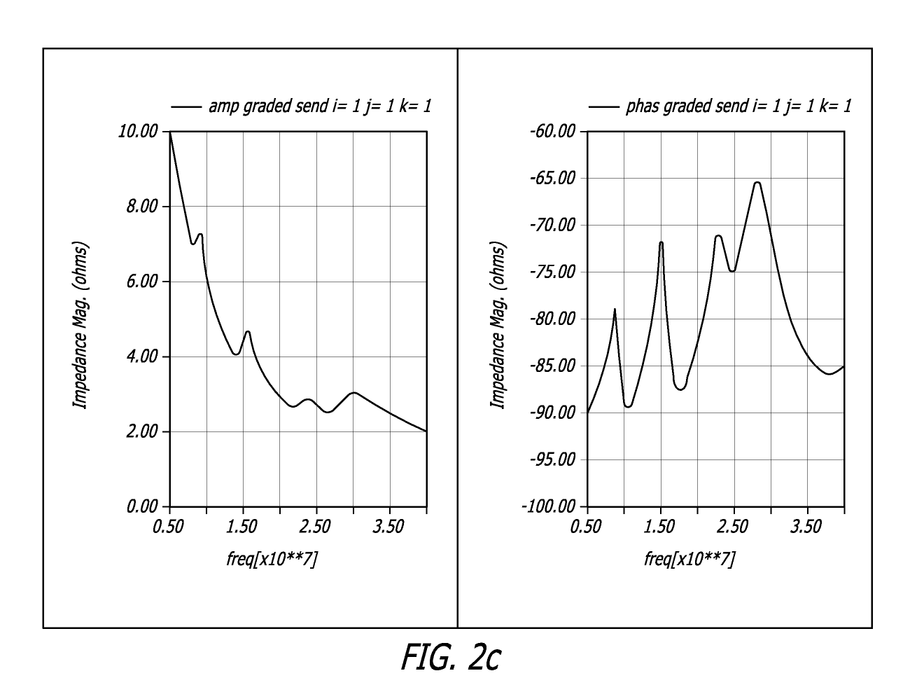

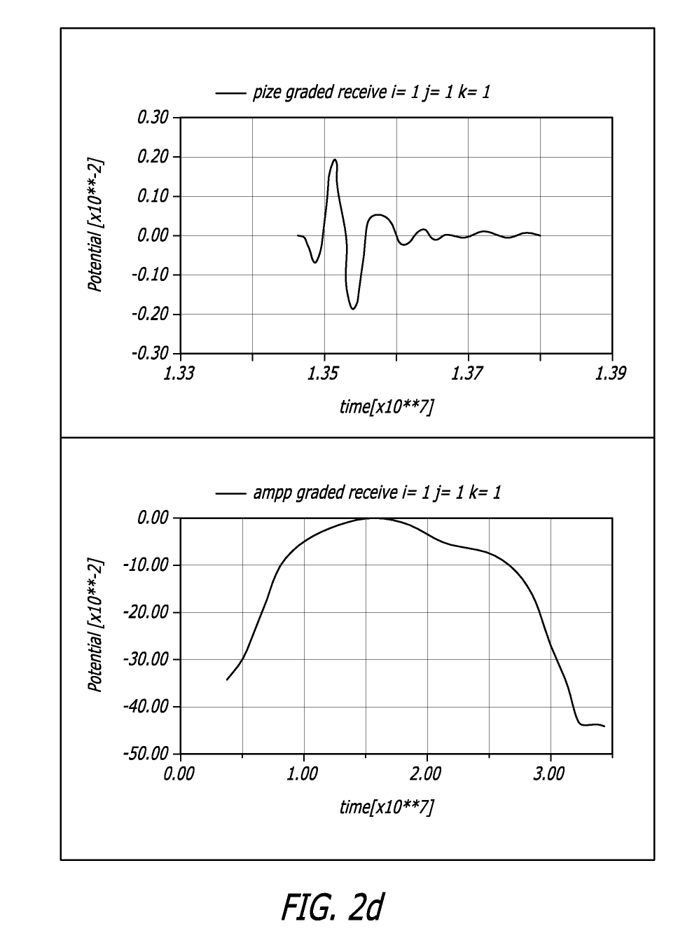

FEA simulation of the 2-2 PbTiO₃ partial composite with rectangular kerfs and the transducer fabricated from this material was carried out by PZFlex (Weidlinger Associates INC, Los Altos, Calif.) with the following specification: the total thickness of PbTiO₃ ceramics was 150 μm, the depth of rectangular kerf was 70 μm. The kerf width was 20 μm and the pillar width between the two kerfs was 20 μm. Electrical impedances of a single partial composite ceramics without kerf filler, partial composites after the filler was applied to the kerfs, and graded transducer are shown in FIG. 2. FIG. 2(a) is the resonant impedance of single partial 2-2 PbTiO₃ plate without kerf filler. This figure shows two resonant impedance peaks, which correspond to the piezoelectric thickness of 80 μm and 150 μm. When the kerfs were filled with the silver epoxy, one new resonant peak appeared between the previous two fundamental resonances appeared [FIG. 2(b)]. The final graded transducer composed of a lossy conductive backing and matching layers of silver/epoxy and parylene showed a 4th resonant peak [FIG. 2(c)]. A traditional piezoelectric resonator has a fundamental resonance and odd-order resonances in the resonant frequency spectrum. The partial composite on the other hand produces two fundamental resonances. The interaction of inactive matching and filler materials with the piezoelectric layer causes other resonant coupled modes to occur. FIG. 2(d) shows the FEA modeling results for pulse-echo performance of the graded transducer. The bandwidth is quite wide reaching a 95% bandwidth at −6 dB.

Experiments

The acoustic performance of the transducer was tested in a degassed, deionized water bath in pulse/echo mode by reflecting the signal off an X-cut quartz target placed at the focal point. For pulse/echo measurements, transducer excitation was achieved with either a Panametrics (Waltham, Mass.) model 5900PR pulser/receiver. The reflector waveforms were received and digitized by 500-MHz LC534 Lecroy (Chestnut Ridge, N.Y.) oscilloscope set to 50Ω coupling. Further information on the experimental arrangement using the Panametrics pulser and Avetech monocycle function generator can be found in references (see J. M. Cannata, T. A. Ritter, W. H. Chen, R. H. Silverman, and K. K. Shung, “Design of Efficient, Broadband Single-Element Ultrasonic Transducers for Medical Imaging Applications,” IEEE Trans. Ultrason., Ferroelect., Freq. Contr., Vol. 50, no. 11, pp. 1548-1557, 2003; and K. A. Snook, J. Z. Zhao, C. H. Alves, J. M. Cannata, W. H. Chen, R. J. Meyer, Jr, T. A. Ritter, and K. K. Shung, “Design, fabrication, and evaluation of high frequency, single-element transducers incorporating different materials,” IEEE Trans. Ultrason., Ferroelect., Freq. Contr., Vol. 49, no. 2, pp. 169-176, 2002, both of which are incorporated herein by reference). The resonant impedance was measured by HP 4194 Impedance Analyzer.

Results

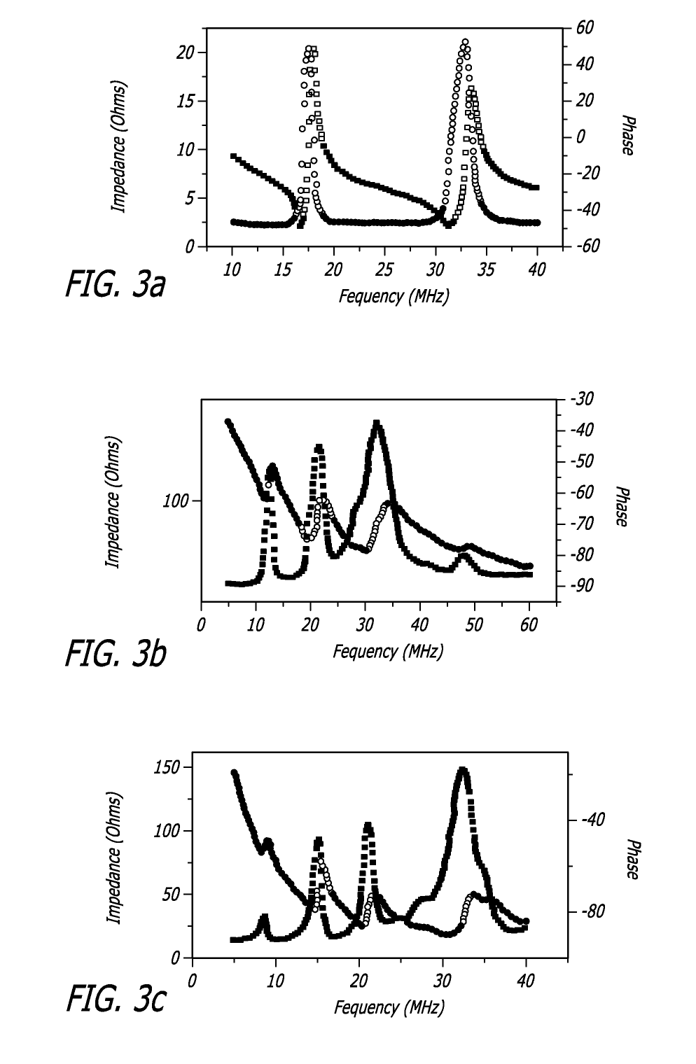

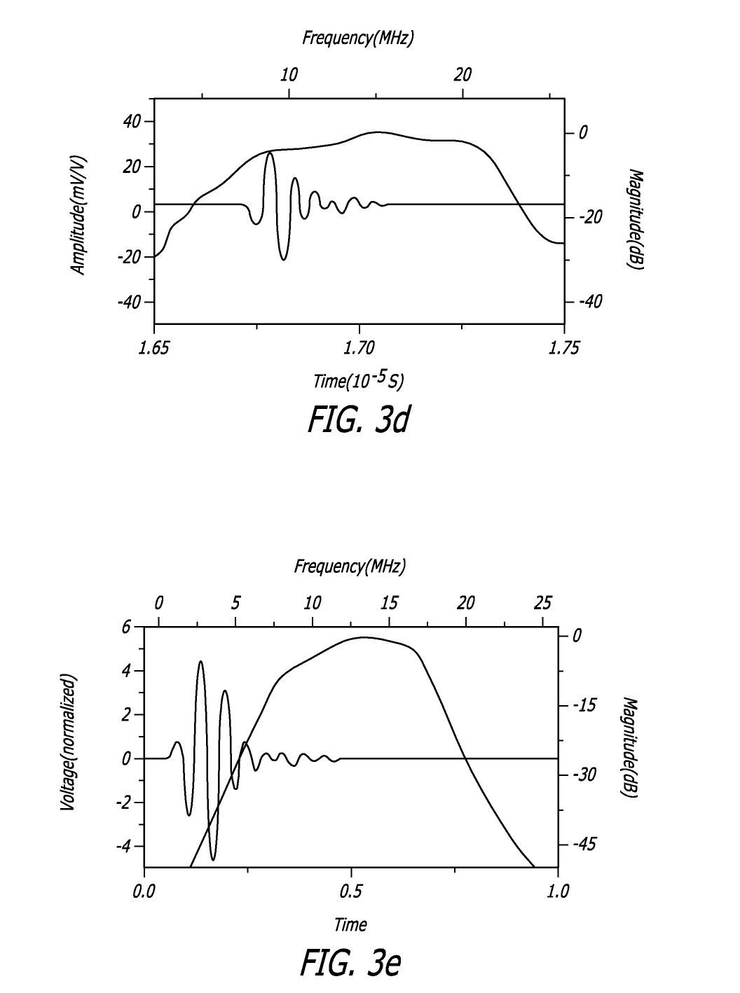

FIG. 3(b) shows the electrical impedance after the kerfs of the graded ceramic were filled with the silver/epoxy filler and a λ/4 silver/epoxy matching layer. FIG. 3(c) shows the result of the final transducer with a second matching layer and backing. The pulse-echo spectra of the graded transducer and the regular bulk ceramic transducer are shown in FIG. 3(d) and FIG. 3(e) respectively. The center frequency is at 15 MHz. The −6 dB bandwidths of partial composite graded transducer and regular uniform transducer are 92%, and 56%, respectively.

### CONCLUSION

In this study, rectangular kerfs were diced on the surface of piezoelectric ceramics to make a partial composite. FEA modeling showed that the partial composites give rise to multiple resonances. Two single element transducers were fabricated to validate the theoretical analyses. The bandwidth of the graded transducer using the partial composite was 92% where as regular uniform transducer was 58%. The experimental results are consistent with the theoretical results. The partial composite can be easily manufactured, and has a relatively lower acoustic impedance. Partial composites, because of their wider bandwidth performance, are very attractive for various applications in medical imaging and nondestructive evaluation.

The components, steps, features, objects, benefits and advantages that have been discussed are merely illustrative. None of them, nor the discussions relating to them, are intended to limit the scope of protection in any way. Numerous other embodiments are also contemplated, including embodiments that have fewer, additional, and/or different components, steps, features, objects, benefits and advantages. The components and steps may also be arranged and ordered differently. In short, the scope of protection is limited solely by the claims that now follow. That scope is intended to be as broad as is reasonably consistent with the language that is used in the claims and to encompass all structural and functional equivalents.

For example, variations on these components, steps, features, objects, benefits and advantages may be found in U.S. Provisional Patent Application Ser. No. 60/701,761, entitled “Fabrication of Broadband Graded Transducer Using Piezoelectric Partial Composites,” filed Jul. 22, 2005, attorney docket number 28080-181, as well as the attachments thereto, the entire content of which (including the attachments) is incorporated herein by reference.

The phrase “means for” when used in a claim embraces the corresponding structure and materials that have been described and their equivalents. Similarly, the phrase “step for” when used in a claim embraces the corresponding acts that have been described and their equivalents. The absence of these phrases means that the claim is not limited to any corresponding structures, materials, or acts.

Nothing that has been stated or illustrated is intended to cause a dedication of any component, step, feature, object, benefit, advantage, or equivalent to the public, regardless of whether it is recited in the claim.

We claim:

1. A broadband transducer comprising a piezoelectric plate having a plurality of substantially rectangular grooves.
